(19) United States
(12) Patent Application Publication
(10) Pub. No.: US 2023/0211268 A1
(43) Pub. Date: Jul. 6, 2023

(54) GAS STREAM GUIDING DEVICE AND MANUFACTURING EQUIPMENT

(71) Applicant: GREENFILTEC LTD., Taoyuan City (TW)

(72) Inventors: Ching-Feng WEN, Taoyuan City (TW); Yu-De LIEN, Taoyuan City (TW)

(73) Assignee: GREENFILTEC LTD., Taoyuan City (TW)

(21) Appl. No.: 18/088,243

(22) Filed: Dec. 23, 2022

Related U.S. Application Data
(60) Provisional application No. 63/295,156, filed on Dec. 30, 2021.

(51) Int. Cl. B01D 46/00; H01L 21/67

(52) U.S. Cl. CPC B01D 46/0041; H01L 21/67017

(57) ABSTRACT

A gas stream guiding device and a manufacturing equipment are provided. The gas stream guiding device is for use with a working bench having a top opening. The gas stream guiding device includes a casing, a gas inlet, a gas outlet, and a stream guiding part. The casing includes an inner space. The gas inlet is disposed on the casing, wherein a gas stream enters the inner space through the gas inlet from the side of the working bench. The gas outlet is disposed on the casing and is connected with the top opening, wherein the gas stream leaves the inner space from the gas outlet and enters the working bench. The stream guiding part is disposed in the casing and is located on the flow path of the gas stream, wherein at least a portion of the stream guiding part extends aside in the direction perpendicular to the gas inlet. The manufacturing equipment includes the gas stream guiding device and the working bench.

### CROSS-REFERENCE TO RELATED APPLICATION

This application claims the priority benefit of U.S. provisional application Ser. No. 63/295,156 filed on Dec. 30, 2021. The entirety of the above-mentioned patent applications is hereby incorporated by reference herein and made a part of this specification.

### BACKGROUND

### Technical Field

The present invention relates to a gas stream guiding device and a manufacturing equipment. More particularly, the present invention relates to a gas stream guiding device and a manufacturing equipment used in semiconductor manufacturing processes.

### Related Art

As the prior art shown in FIG. 1, in semiconductor manufacturing processes, in order to reduce the effect of dust, organic and inorganic pollutants to objects such as wafers and chips, the objects are disposed for operation on a working table 71 in a working bench 70, wherein filtration to the gas stream entering the working bench 70 is executed.

As the prior art shown in FIG. 1, to increase the space of working, a gas stream usually enters the conventional working bench 70 from the side through a gas inlet 20 of a gas entering device 10 disposed on the top of the working bench 70, and is filtered by a filter 51. In this approach, however, the flow velocity of the gas stream passing through the filter 51 isn't uniform, wherein a turbulence status is easily formed. Therefore, the chance for contaminating the objects on the working table is increased, and hence reduces the yield and increases the manufacturing cost. As such, the conventional approach is still improvable.

### SUMMARY

One of objectives of the present invention is to provide a gas stream guiding device, capable of increasing the yield and decreasing the manufacturing cost.

One of objectives of the present invention is to provide a manufacturing equipment, capable of increasing the yield and decreasing the manufacturing cost.

The gas stream guiding device of the present invention is for use with a working bench having a top opening, which includes a casing, a gas inlet, a gas outlet, and a stream guiding part. The casing includes an inner space. The gas inlet is disposed on the casing, wherein a gas stream enters the inner space through the gas inlet from the side of the working bench. The gas outlet is disposed on the casing in a position other than the gas inlet. The gas outlet connects to the top opening. The gas stream leaves the inner space from the gas outlet and enters the working bench. The stream guiding part is disposed in the casing and located on the flow path of the gas stream, wherein at least a portion of the stream guiding part extends aside in the direction perpendicular to the gas inlet.

In one embodiment, the top opening faces substantially the Z-axis direction, and the Z-axis direction is orthogonal to the X-axis direction and the Y-axis direction. The gas inlet is disposed on the casing, wherein the gas inlet faces substantially the X-axis direction and connects with the inner space. The gas outlet is disposed on the casing in a position other than the gas inlet, wherein the gas outlet faces substantially the Z-axis direction and connects with the inner space. The gas outlet connects to the top opening. The stream guiding part is disposed in the casing, wherein at least a portion of the stream guiding part extends from the direction parallel to the X-axis to the direction along the Y-axis.

In one embodiment, the stream guiding part forms an arc face.

In one embodiment, the vertical projection of the casing on a plane on which the top opening is located is snail-shell-shaped.

In one embodiment, the casing includes a top shell, a bottom shell, and a side shell disposed between the top shell and the bottom shell. The gas inlet and the gas outlet are disposed respectively on the side shell and the bottom shell.

In one embodiment, a portion of the inner face of the side shell forms the stream guiding part.

In one embodiment, the stream guiding part is disposed on the top shell.

In one embodiment, the gas stream guiding device further includes a gas homogenizing unit disposed in the gas outlet.

In one embodiment, the gas homogenizing unit includes a plurality of holes.

In one embodiment, the gas homogenizing unit is disk-shaped. The gas homogenizing unit is trisected into a first area, a second area, and a third area from the center in accordance with its radius. The diameter of each of the plurality of holes in the first area is one third of the diameter of each of the plurality of holes in the second area. The diameter of each of the plurality of holes in the second area is one third of the diameter of each of the plurality of holes in the third area.

In one embodiment, the gas stream guiding device further includes a filter disposed in the gas outlet.

The manufacturing equipment of the present invention includes the working bench and the gas stream guiding device. The working bench further includes a working table, wherein the top opening directly faces the top face of the working table.

### BRIEF DESCRIPTION OF THE DRAWINGS

FIG. 1 is a schematic diagram of prior art.

FIGS. 2A and 2B are schematic diagrams of an embodiment of a manufacturing equipment according to the present invention.

FIGS. 3A to 3D are schematic diagrams of an embodiment of a gas stream guiding device according to the present invention.

FIG. 3E is a schematic diagram of an embodiment of a gas stream guiding device according to the present invention having a stream guiding part disposed on the top shell.

FIG. 4A is a schematic diagram showing the measured position of the gas outlet of prior art.

FIG. 4B is a schematic diagram showing the measured position of the gas outlet of the present invention.

### DETAILED DESCRIPTION

Implementations of a connection assembly disclosed by the present invention are described below by using particular and specific embodiments with reference to the drawings, and a person skilled in the art may learn of advantages and effects of the present invention from the disclosure of this specification. However, the following disclosure is not intended to limit the protection scope of the present invention, and a person skilled in the art may carry out the present invention by using other different embodiments based on different viewpoints without departing from the concept and spirit of the present invention. In the accompanying drawings, plate thicknesses of layers, films, panels, regions, and the like are enlarged for clarity. Throughout the specification, same reference numerals indicate same elements. It should be understood that when an element such as a layer, film, region or substrate is referred to as being “on” or “connected” to another element, it may be directly on or connected to another element, or intervening elements may also be present. In contrast, when an element is referred to as being “directly on” or “directly connected to” another element, there is no intervening element present. As used herein, “connection” may refer to a physical and/or electrical connection. Further, “electrical connecting” or “coupling” may indicate that another element exists between two elements.

It should be noted that the terms “first”, “second”, “third”, and the like that are used in the present disclosure can be used for describing various elements, components, regions, layers and/or portions, but the elements, components, regions, layers and/or portions are not limited by the terms. The terms are merely used to distinguish one element, component, region, layer, or portion from another element, component, region, layer, or portion. Therefore, the “first element”, “component”, “region”, “layer”, or “portion” discussed below may be referred to as a second element, component, region, layer, or portion without departing from the teaching of this disclosure.

In addition, relative terms, such as “down” or “bottom” and “up” or “top”, are used to describe a relationship between an element and another element, as shown in the figures. It should be understood that the relative terms are intended to include different orientations of a device in addition to orientations shown in the figures. For example, if a device in a figure is turned over, an element that is described to be on a “lower” side of another element is directed to be on an “upper” side another element. Therefore, the exemplary terms “down” may include orientations of “down” and “up” and depends on a particular orientation of an accompanying drawing. Similarly, if a device in a figure is turned over, an element that is described as an element “below” another element or an element “below” is directed to be “above” another element. Therefore, the exemplary terms “below” or “below” may include orientations of up and down.

As used herein, “about”, “approximately”, or “substantially” is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, ±20%, ±10%, ±5% of the stated value. Further, as used herein, “about”, “approximately”, or “substantially” may depend on optical properties, etch properties, or other properties to select a more acceptable range of deviations or standard deviations without one standard deviation for all properties.

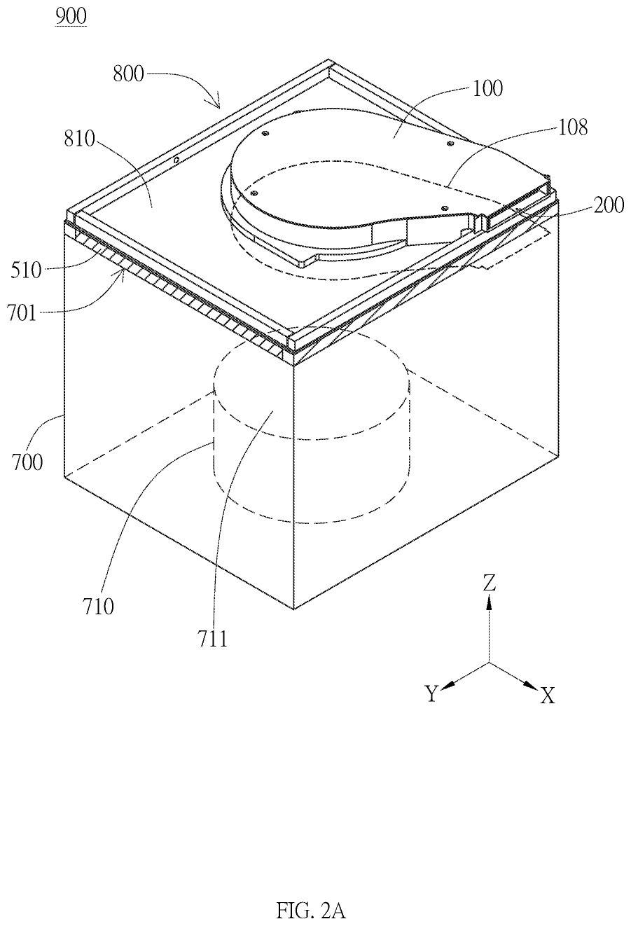

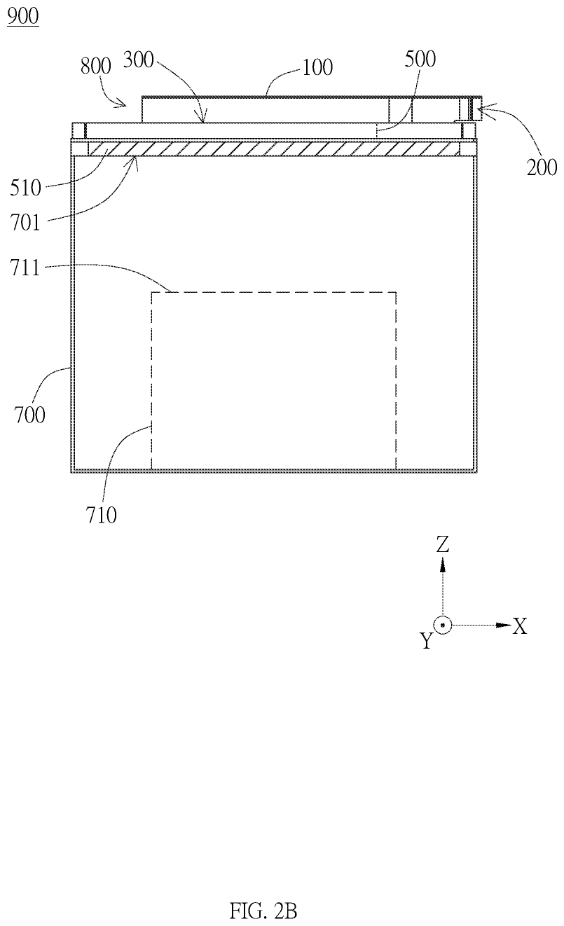

As shown in the embodiment in FIGS. 2A and 2B, the gas stream guiding device 800 of the present invention is for use with a working bench 700 having a top opening 701. The working bench 700 and the gas stream guiding device 800 form the manufacturing equipment 900 of the present invention. The working bench 700 further includes a working table 710, wherein the top opening 701 directly faces the top face 711 of the working table 710. More particularly, the manufacturing equipment 900 is used in semiconductor manufacturing processes, wherein objects such as wafers, semiconductor chips, etc. can be disposed on the working table 710. A gas stream enters the gas stream guiding device 800 from the side of the working bench through the gas inlet 200, leaves from the gas outlet 300, and enters the working bench 700 through the top opening 701. In one embodiment, the gas stream guiding device 800 can be fitted to the top opening 701 via a cover plate 810, making the working bench 700 form an enclosed space. In different embodiments, however, the size of the casing 100 of the gas stream guiding device 800 can be modified to make the gas stream guiding device 800 fitted directly to the top opening 701, making the working bench 700 form an enclosed space. The gas stream guiding device can further include a filter 510 disposed in the gas outlet 300, more specifically, between the gas outlet 300 and the top opening 701, to filter pollutants such as micro particles, VOC, etc. The filter 510 is preferably but not limited to a removable one.

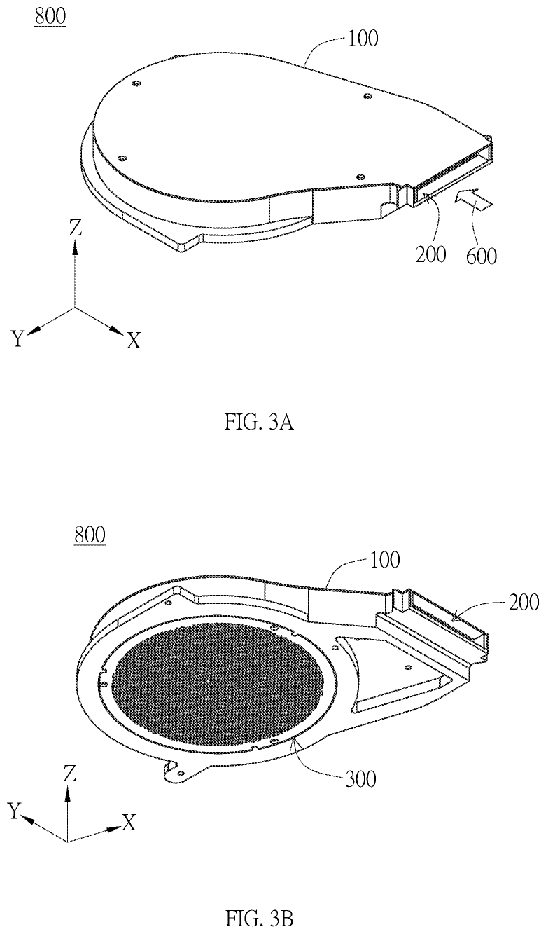

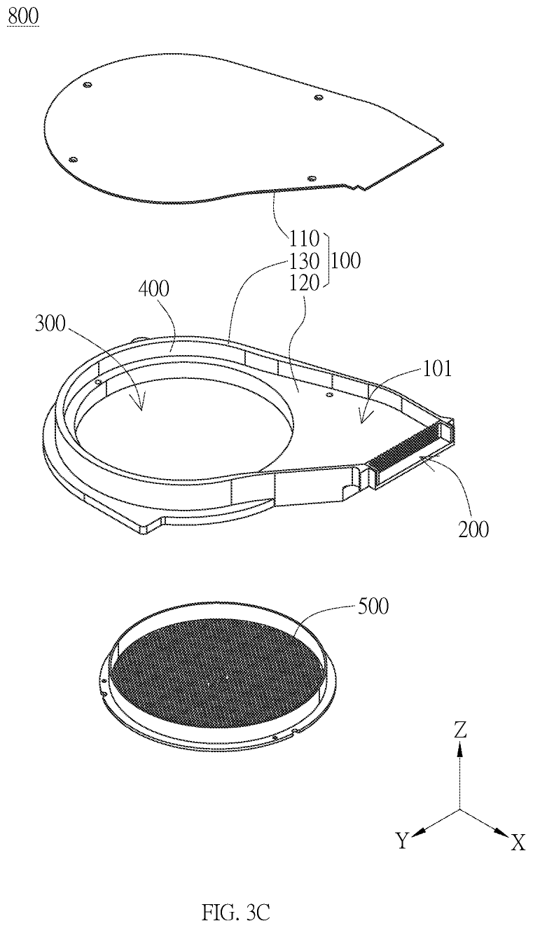

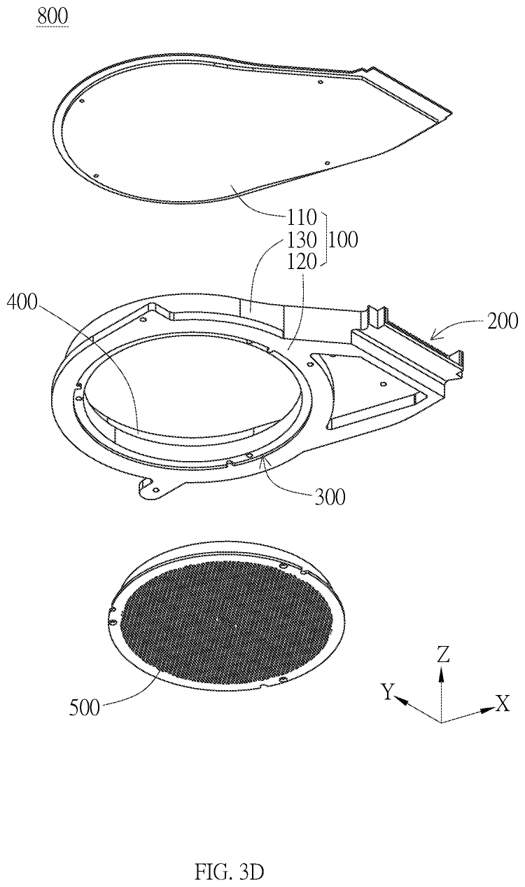

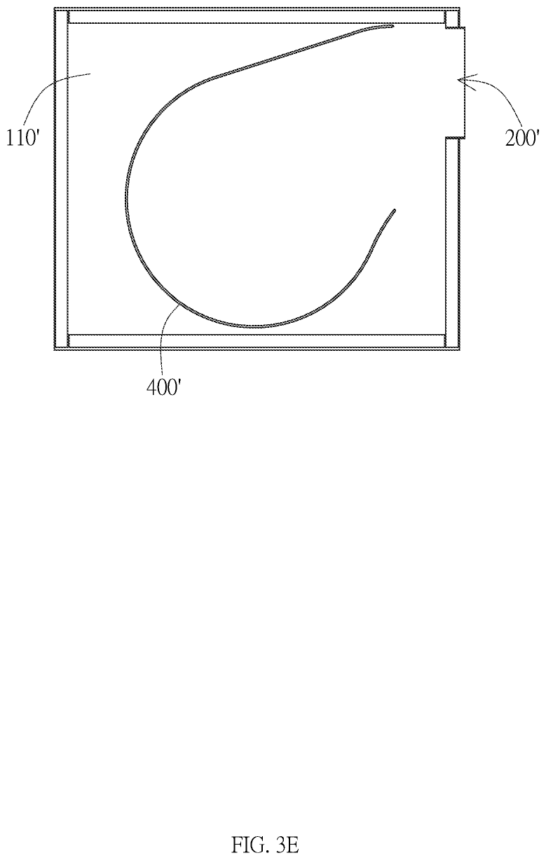

More particularly, as shown in the embodiment in FIGS. 3A to 3D, the gas stream guiding device 800 includes a casing 100, a gas inlet 200, a gas outlet 300, and a stream guiding part 400. In one embodiment, the gas stream guiding device 800 is made of polymer. In different embodiments, however, the gas stream guiding device 800 can be entirely or partially made of materials other than polymer, such as metal or alloy.

The casing 100 includes an inner space 101. The gas inlet 200 is disposed on the casing 100, wherein the gas stream 600 enters the inner space 101 through the gas inlet 200 from the side of the working bench 700 (see FIG. 2A). The gas outlet 300 is disposed on the casing 100 in a position other than the gas inlet 200. The gas outlet 300 connects to the top opening 701 (see FIG. 2A) and allows the gas stream to leave the inner space 101 from the gas outlet 300 and enter the working bench 700. More particularly, in one embodiment, the casing 100 includes a top shell 110, a bottom shell 120, and a side shell 130 disposed between the top shell 110 and the bottom shell 120. The gas inlet 200 and the gas outlet 300 are disposed respectively on the side shell 130 and the bottom shell 120.

As shown in the embodiment in FIGS. 3A to 3D, the stream guiding part 400 is disposed in the casing 100 and located on the flow path of the gas stream, wherein at least a portion of the stream guiding part 400 extends aside in the direction perpendicular to the gas inlet 200. In this embodiment, a portion of the inner face of the side shell 130 forms the stream guiding part 400 which is an arc face. Specifically, the vertical projection 108 of the casing 100 on the plane on which the top opening 701 (see FIG. 2A) is located is snail-shell-shaped, wherein the gas inlet 200 corresponds to the opening of the snail-shell-shaped vertical projection 108 of the casing 100. In different embodiments, however, the stream guiding part 400 may have different shapes and structures for guiding gas streams and isn't limited to being formed on the inner face of the side shell 130. As shown in the different embodiment in FIG. 3E, the stream guiding part 400 is an arc retaining wall disposed on the top shell 110′. The gas stream can be guided by the stream guiding part 400 after it enters the casing from the gas inlet 200′. In other words, the shape of the stream guiding part isn't restricted by the shape of the external outline of the casing.

As shown in the embodiment in FIGS. 2A to 3D, from a different point of view, the top opening 701 faces substantially the Z-axis direction, and the Z-axis direction is orthogonal to the X-axis direction and the Y-axis direction. The gas inlet 200 is disposed on the casing 100, wherein the gas inlet 200 faces substantially the X-axis direction and connects with the inner space 101. The gas outlet 300 is disposed on the casing 100 in a position other than the gas inlet 200, wherein the gas outlet 300 faces substantially to the Z-axis direction and connects with the inner space 101. The gas outlet connects to the top opening. The stream guiding part 400 is disposed in the casing 100, wherein at least a portion of the stream guiding part 400 extends from the direction parallel to the X-axis to the direction along the Y-axis.

As shown in the embodiment in FIGS. 3C and 3D, the gas stream guiding device 800 may include a gas homogenizing unit 500 disposed in the gas outlet 300 for making the gas velocity at different positions in the gas outlet more uniform. The gas homogenizing unit 500 may include a plurality of holes. More particularly, the gas homogenizing unit 500 is disk-shaped. The gas homogenizing unit 500 is trisected into a first area, a second area, and a third area from the center in accordance with its radius. The diameter of each of the plurality of holes in the first area is one third of the diameter of each of the plurality of holes in the second area. The diameter of each of the plurality of holes in the second area is one third of the diameter of each of the plurality of holes in the third area. In different embodiments, the holes can have different shapes or distribution.

Tests were applied to the manufacturing equipment of prior art and the manufacturing equipment of the present invention.

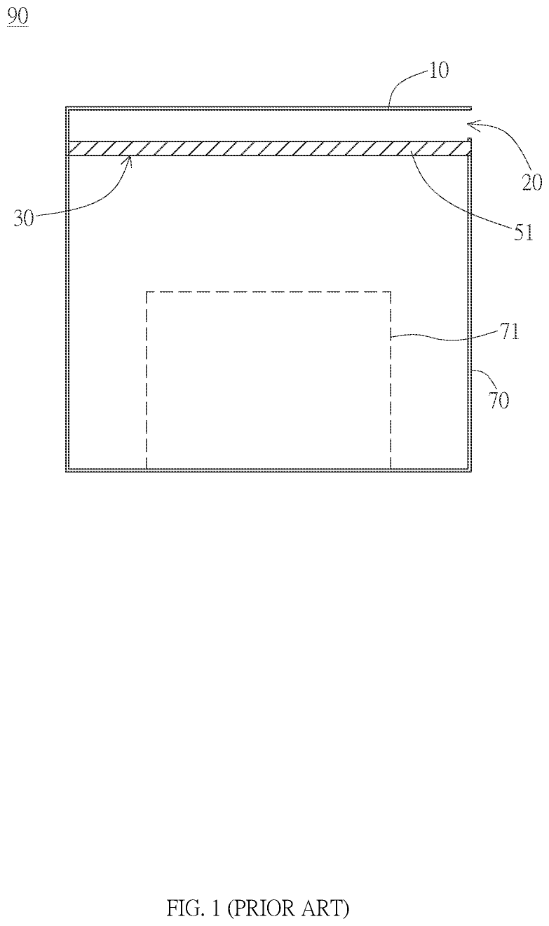

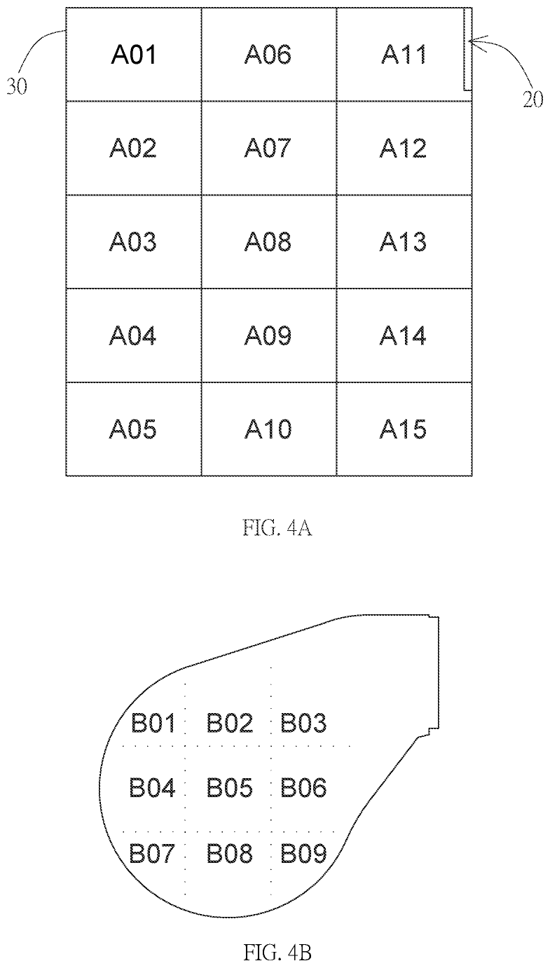

As shown in the embodiment in FIG. 4A, regarding the manufacturing equipment of prior art, the size of the gas outlet 30 (see FIG. 1) is 762 mm in length and 652 mm in width, wherein the size of the gas inlet 20 is 100 mm in length and 50 mm in width. The gas velocity in the inlet is 0.6 m/s. The gas velocity in positions A01-A15 in the outlet were measured and listed in Table 1.

TABLE 1

| | | |
|---|---|---|
| position: A01 | position: A06 | position: A11 |
| gas velocity: 0.10 m/s | gas velocity: 0.08 m/s | gas velocity: 0.17 m/s |
| position: A02 | position: A07 | position: A12 |
| gas velocity: 0.14 m/s | gas velocity: 0.28 m/s | gas velocity: 0.18 m/s |
| position: A03 | position: A08 | position: A13 |
| gas velocity: 0.08 m/s | gas velocity: 0.17 m/s | gas velocity: 0.10 m/s |
| position: A04 | position: A09 | position: A14 |
| gas velocity: 0.06 m/s | gas velocity: 0.12 m/s | gas velocity: 0.05 m/s |
| position: A05 | position: A10 | position: A15 |
| gas velocity: 0.14 m/s | gas velocity: 0.20 m/s | gas velocity: 0.16 m/s |

As shown in Table 1, there is considerable disparity in the gas velocity in different positions in the outlet of prior art since not only gas velocity as high as 0.28 m/s was measured but also gas velocity as low as 0.13 m/s. On the other hand, the average gas velocity in positions A01-A15 is 0.13 m/s, wherein STD is 0.07. The gas velocity in different positions in the outlet of prior art is obviously not uniform.

As shown in the embodiment in FIG. 4B, regarding one embodiment of the manufacturing equipment of the present invention, the size of the gas outlet 300 is 400 mm in diameter, wherein the size of the gas inlet 200 is 200 mm in length and 50 mm in width. The gas velocities in the inlet are respectively 0.45 m/s, 0.75 m/s, and 1.20 m/s. The gas velocities in positions B01-B09 in the outlet were measured and listed in Tables 2A to 2C.

TABLE 2A
(gas velocity in the inlet: 0.45 m/s)

| | | |
|---|---|---|
| position: B01 | position: B02 | position: B03 |
| gas velocity: 0.09 m/s | gas velocity: 0.08 m/s | gas velocity: 0.09 m/s |
| position: B04 | position: B05 | position: B06 |
| gas velocity: 0.10 m/s | gas velocity: 0.08 m/s | gas velocity: 0.09 m/s |
| position: B07 | position: B08 | position: B09 |
| gas velocity: 0.11 m/s | gas velocity: 0.11 m/s | gas velocity: 0.10 m/s |

The average gas velocity in positions B01-B09 is 0.09 m/s, wherein STD is 0.01. The gas velocity in different positions in the outlet of the present invention is obviously uniform.

TABLE 2B
(gas velocity in the inlet: 0.75 m/s)

| | | |
|---|---|---|
| position: B01 | position: B02 | position: B03 |
| gas velocity: 0.18 m/s | gas velocity: 0.15 m/s | gas velocity: 0.16 m/s |
| position: B04 | position: B05 | position: B06 |
| gas velocity: 0.16 m/s | gas velocity: 0.16 m/s | gas velocity: 0.16 m/s |
| position: B07 | position: B08 | position: B09 |
| gas velocity: 0.18 m/s | gas velocity: 0.20 m/s | gas velocity: 0.18 m/s |

The average gas velocity in positions B01-B09 is 0.17 m/s, wherein STD is 0.02. The gas velocity in different positions in the outlet of the present invention is obviously uniform.

TABLE 2C
(gas velocity in the inlet: 1.20 m/s)

| | | |
|---|---|---|
| position: B01 | position: B02 | position: B03 |
| gas velocity: 0.32 m/s | gas velocity: 0.21 m/s | gas velocity: 0.20 m/s |
| position: B04 | position: B05 | position: B06 |
| gas velocity: 0.25 m/s | gas velocity: 0.27 m/s | gas velocity: 0.29 m/s |
| position: B07 | position: B08 | position: B09 |
| gas velocity: 0.28 m/s | gas velocity: 0.29 m/s | gas velocity: 0.28 m/s |

The average gas velocity in positions B01-B09 is 0.27 m/s, wherein STD is 0.04. The gas velocity in different positions in the outlet of the present invention is obviously uniform.

Moreover, evaluation regarding energy consumption was applied to the manufacturing equipment of prior art and the manufacturing equipment of the present invention. A gas stream was input by a blower. In one embodiment, the inlet gas flow volume of the two were made equal, wherein the outlet gas flow volume of the two were measured and listed in Table 3A.

TABLE 3A

| | inlet area | inlet gas flow | outlet area | outlet gas flow |
|---|---|---|---|---|
| | (m²) | volume (m³/h) | (m²) | volume (m³/h) |
| the equipment | 0.01 | 86.4 | 0.42 | 0.06 |
| of prior art | | | | |
| the gas stream | 0.01 | 86.4 | 0.08 | 0.30 |
| guiding device | | | | |
| of the present | | | | |
| invention | | | | |

As shown in Table 3A, the outlet area of the gas stream guiding device of the present invention is about one fifth (⅕) of the outlet area of prior art. When the inlet gas flow volume of the two are equal, the outlet gas flow volume of the gas stream guiding device of the present invention is about five times the outlet gas flow volume of prior art, wherein there is no significant difference regarding the energy consumption of the blowers for use with the gas stream guiding device of the present invention and prior art. In other words, with the same energy consumption, in comparison with prior art, the outlet gas flow volume of the gas stream guiding device of the present invention would be larger.

In one embodiment, the outlet gas flow volume of the two were made equal, wherein the inlet gas flow volume of the two were measured and listed in Table 3B.

TABLE 3B

| | inlet area | inlet gas flow | outlet area | outlet gas flow |
|---|---|---|---|---|
| | (m²) | volume (m³/h) | (m²) | volume (m³/h) |
| the equipment | 0.01 | 450.0 | 0.42 | 0.30 |
| of prior art | | | | |
| the gas stream | 0.01 | 86.4 | 0.08 | 0.30 |
| guiding device | | | | |
| of the present | | | | |
| invention | | | | |

As shown in Table 3B, the outlet area of the gas stream guiding device of the present invention is about one fifth (⅕) the outlet area of prior art. When the outlet gas flow volume of the two are equal, the inlet gas flow volume of the gas stream guiding device of the present invention is about one fifth the inlet gas flow volume of prior art, wherein the inlet area of the gas stream guiding device of the present invention is equal to the inlet area of prior art. Hence, regarding the blowers for use with the gas stream guiding device of the present invention and prior art, the output gas flow volume of the former is about one fifth that of the latter. In other words, with the same outlet gas flow volume, in comparison with prior art, the energy consumption of the gas stream guiding device of the present invention would be lower.

On the other hand, one can find by observing the contamination status of the objects on the working tables of prior art and of the manufacturing equipment of the present invention that, under the condition of gas flow only, 9 to 23 counts of contamination are observed on the working tables of prior art, as opposed to no contamination observed on the working tables of the manufacturing equipment of the present invention. Under the condition of acid solution wash, 11 to 41 counts of contamination are observed on the working tables of prior art, as opposed to 4 counts of contamination observed on the working tables of the manufacturing equipment of the present invention.

Based on the above, one can see that, with the stream guiding part, the gas stream entering the gas stream guiding device of the present invention through the gas inlet can pass through the gas outlet with more uniform velocity, and it can enter the working bench through the top opening, which makes the gas stream inside the working bench stable. As a result, the chance for the objects on the working table to be contaminated is decreased. Hence the present invention is capable of increasing the yield and decreasing the manufacturing cost. Moreover, it has the advantage of lower energy consumption.

The present invention is described by means of the above-described relevant embodiments. However, the above-described embodiments are only examples for implementing the present invention. It should be pointed out that the disclosed embodiments do not limit the scope of the present invention. In contrast, the spirit included in the scope of the patent application and modifications and equivalent settings made within the scope are all included in the scope of the present invention.

What is claimed is:

1. A gas stream guiding device for use with a working bench having a top opening, comprising:
a casing including an inner space;
a gas inlet disposed on the casing, wherein a gas stream enters the inner space through the gas inlet from the side of the working bench;
a gas outlet disposed on the casing in a position other than the gas inlet, wherein the gas outlet connects to the top opening, wherein the gas stream leaves the inner space from the gas outlet and enters the working bench; and
a stream guiding part disposed in the casing and located on the flow path of the gas stream, wherein at least a portion of the stream guiding part extends aside in the direction perpendicular to the gas inlet.

2. The gas stream guiding device according to claim 1, wherein the stream guiding part forms an arc face.

3. The gas stream guiding device according to claim 1, wherein the vertical projection of the casing on a plane on which the top opening is located is snail-shell-shaped, wherein the gas inlet corresponds to the opening of the snail-shell-shaped vertical projection of the casing.

4. The gas stream guiding device according to claim 1, wherein the casing includes a top shell, a bottom shell, and a side shell disposed between the top shell and the bottom shell, wherein the gas inlet and the gas outlet are disposed respectively on the side shell and the bottom shell.

5. The gas stream guiding device according to claim 4, wherein a portion of the inner face of the side shell forms the stream guiding part.

6. The gas stream guiding device according to claim 4, wherein the stream guiding part is disposed on the top shell.

7. The gas stream guiding device according to claim 1, further comprising a gas homogenizing unit disposed in the gas outlet.

8. The gas stream guiding device according to claim 7, wherein the gas homogenizing unit includes a plurality of holes.

9. The gas stream guiding device according to claim 8, wherein the gas homogenizing unit is disk-shaped, wherein the gas homogenizing unit is trisected into a first area, a second area, and a third area from the center in accordance with its radius, wherein the diameter of each of the plurality of holes in the first area is one third of the diameter of each of the plurality of holes in the second area, wherein the diameter of each of the plurality of holes in the second area is one third of the diameter of each of the plurality of holes in the third area.

10. A manufacturing equipment comprising the working bench and the gas stream guiding device according to claim 1, wherein the working bench further includes a working table, wherein the top opening directly faces the top face of the working table.

11. A gas stream guiding device for use with a working bench having a top opening, wherein the top opening faces substantially the Z-axis direction, and the Z-axis direction is orthogonal to the X-axis direction and the Y-axis direction, the gas stream guiding device comprising:
a casing including an inner space;
a gas inlet disposed on the casing, wherein the gas inlet faces substantially the X-axis direction and connects with the inner space;
a gas outlet disposed on the casing in a position other than the gas inlet, wherein the gas outlet faces substantially the Z-axis direction and connects with the inner space, wherein the gas outlet connects to the top opening; and
a stream guiding part disposed in the casing, wherein at least a portion of the stream guiding part extends from the direction parallel to the X-axis to the direction along the Y-axis.

12. The gas stream guiding device according to claim 11, wherein the stream guiding part forms an arc face.

13. The gas stream guiding device according to claim 11, wherein the vertical projection of the casing on a plane on which the top opening is located is snail-shell-shaped, wherein the gas inlet corresponds to the opening of the snail-shell-shaped vertical projection of the casing.

14. The gas stream guiding device according to claim 11, wherein the casing includes a top shell, a bottom shell, and a side shell disposed between the top shell and the bottom shell, wherein the gas inlet and the gas outlet are disposed respectively on the side shell and the bottom shell.

15. The gas stream guiding device according to claim 14, wherein a portion of the inner face of the side shell forms the stream guiding part.

16. The gas stream guiding device according to claim 14, wherein the stream guiding part is disposed on the top shell.

17. The gas stream guiding device according to claim 11, further comprising a gas homogenizing unit disposed in the gas outlet.

18. The gas stream guiding device according to claim 17, wherein the gas homogenizing unit includes a plurality of holes.

19. The gas stream guiding device according to claim 18, wherein the gas homogenizing unit is disk-shaped, wherein the gas homogenizing unit is trisected into a first area, a second area, and a third area from the center in accordance with its radius, wherein the diameter of each of the plurality of holes in the first area is one third of the diameter of each of the plurality of holes in the second area, wherein the diameter of each of the plurality of holes in the second area is one third of the diameter of each of the plurality of holes in the third area.

20. The gas stream guiding device according to claim 11, further comprising a filter disposed in the gas outlet.
